(19) United States
(12) Patent Application Publication
(10) Pub. No.: US 2012/0120594 A1
(43) Pub. Date: May 17, 2012

(54) HEAT DISSIPATING CASING STRUCTURE FOR MAIN BOARD

(76) Inventors: TIEN-SHENG HUANG, Taichung City (TW); Yi-Lun Huang, Tanzi Township (TW)

(21) Appl. No.: 12/944,754

(22) Filed: Nov. 12, 2010

(51) Int. Cl. G06F 1/20; H05K 7/20

(52) U.S. Cl. 361/679.47; 361/720

(57) ABSTRACT

The heat dissipating casing structure contains a metallic casing, a metallic heat conducting block, and a heat conducting paste. The heat conducting block is positioned inside and attached to the casing. The heat conducting paste is disposed on the heat conducting block. When a main board is positioned inside the casing, the heat conducting paste is behind a heat source of the main board and is attached to the main board. The heat produced by the heat source therefore could be conducted to the casing through the heat conducting paste and the heat conducting block. By the large exposure area of the casing to the outside atmosphere, the heat could be easily dissipated, even after power is turned off.

### (A) TECHNICAL FIELD OF THE INVENTION

The present invention generally relates to computer casing, and especially relates to a heat dissipating casing structure for conducting heat of a main board to the casing for dissipation.

### (B) DESCRIPTION OF THE PRIOR ART

The electronic components on a main board, such as the central processing unit and the Northbridge/Southbridge chip are the main heat sources. If the produced heat could not be properly dissipated, the main board's performance could be adversely affected and sometimes the electronic components could be burned down. Conventionally, some heat dissipating means such as fans is configured on the heat sources. However, when the power to the main board is turned off, the heat dissipating means also stops functioning while residual heat is still accumulated inside the casing and could deteriorate the electronic components.

In addition, as more main boards are installed in the casing at an angle relative to the ground. The heat dissipating means, such as fan and heat dissipating fins, would exert a torque to the main board. Together with the heat conducted to the main board that could soften the main board, the main board is often bended after a period of usage, causing more severe damage.

Further more, as the electronic components on the main board are usually accompanied with coatings of chemical substances for, for example, reducing their interference. As heat is accumulated inside the casing, the chemical substances would evaporate and produce toxic material. The toxic material could be distributed to outside the casing, presenting a hazard to the users.

### SUMMARY OF THE INVENTION

A novel heat dissipating casing structure is provided herein, which conducts the heat from a main board directly to the casing to achieve heat exchange with outside cool air for faster and more efficient heat dissipation. Even after power is turned off, the heat dissipating structure is able to continue functioning, overcoming the conventional problem of heat being accumulated inside the casing after power is turned off.

The heat dissipating casing structure contains a metallic casing, a metallic heat conducting block, and a heat conducting paste. The heat conducting block is positioned inside and attached to the casing. The heat conducting paste is disposed on the heat conducting block. When a main board is positioned inside the casing, the heat conducting paste is behind a heat source of the main board and is attached to the main board.

The heat produced by the heat source therefore could be conducted to the casing through the heat conducting paste and the heat conducting block. By the large exposure area of the casing to the outside atmosphere, the heat could be easily dissipated, even after power is turned off.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a schematic perspective diagram showing a heat dissipating casing structure according to an embodiment of the present invention.

FIG. 2 is a perspective diagram showing the heat dissipating casing structure of FIG. 1 further equipped with heat dissipating fins.

FIG. 3 is a perspective diagram showing the heat dissipating casing structure of FIG. 2 with a door configured on a top side.

FIG. 4 is a perspective diagram showing a metallic handle configured on the heat dissipating casing structure of FIG. 1.

FIG. 5 is a perspective diagram showing the metallic handle of FIG. 4 from a different angle.

FIG. 6 is a perspective diagram showing a metallic handle configured on the heat dissipating casing structure of FIG. 2.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

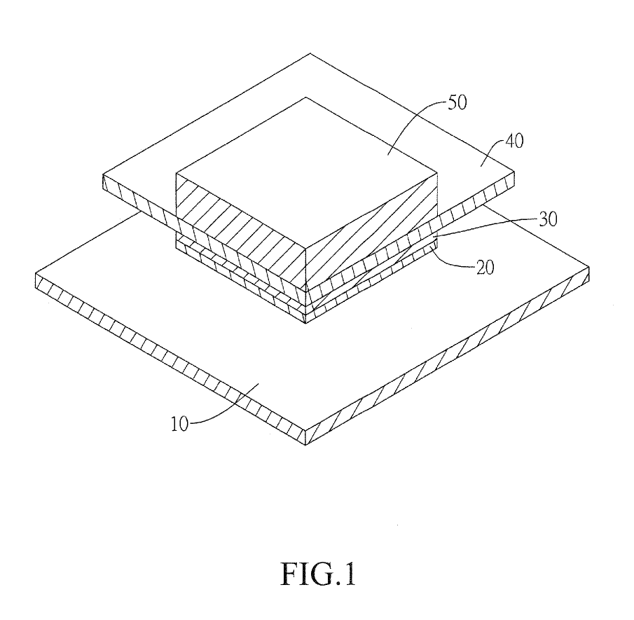

As shown in FIG. 1, a heat dissipating casing structure according to an embodiment of the present invention contains a metallic casing 10, a metallic heat conducting block 20, and a heat conducting paste 30.

The heat conducting block 20 is positioned inside and attached to the casing 10. The heat conducting paste 30 is disposed on the heat conducting block 20. When a main board 40 is positioned inside the casing 10, the heat conducting paste 30 is behind a heat source 50 of the main board 40 and is attached to the main board 40.

The heat source 50 could be the central processing unit (CPU), or a Northbridge/Southbridge chip, or any other electronic component on the main board 40 capable of producing heat. In the present embodiment, it is assumed that the heat source 50 is a CPU.

The heat produced by the heat source 50 would be conducted to the main board 40, and then to the casing 10 through the heat conducting paste 30 and the heat conducting block 20. By the large exposure area of the casing 10 to the outside atmosphere, the heat could be easily dissipated. In other words, a path is provided for the heat to reach the outside atmosphere, in contrast to the prior art's containing heat inside. Further more, this path does not require any electricity and moving parts, and therefore could continue function even after power is turned off.

As such, the present invention is able to prevent heat from accumulating inside the casing 10 and thereby protects the electronic components on the main board 40, avoids chemical substances from evaporation, and obviates the main board 40 from overheating and warping.

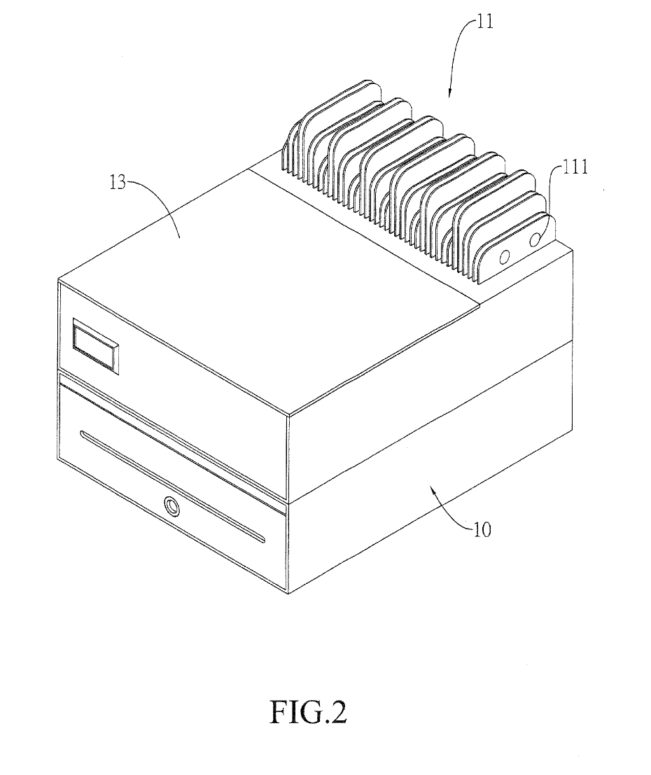

As shown in FIG. 2, the casing 10 is further configured with a number of heat dissipating fins 11 for increasing the contacting area with air and thereby enhancing the heat dissipating efficiency. The fins 11 could be further threaded by a heat dissipating pipe 111 for distributing heat among the fins 11 to further enhance the heat dissipating efficiency.

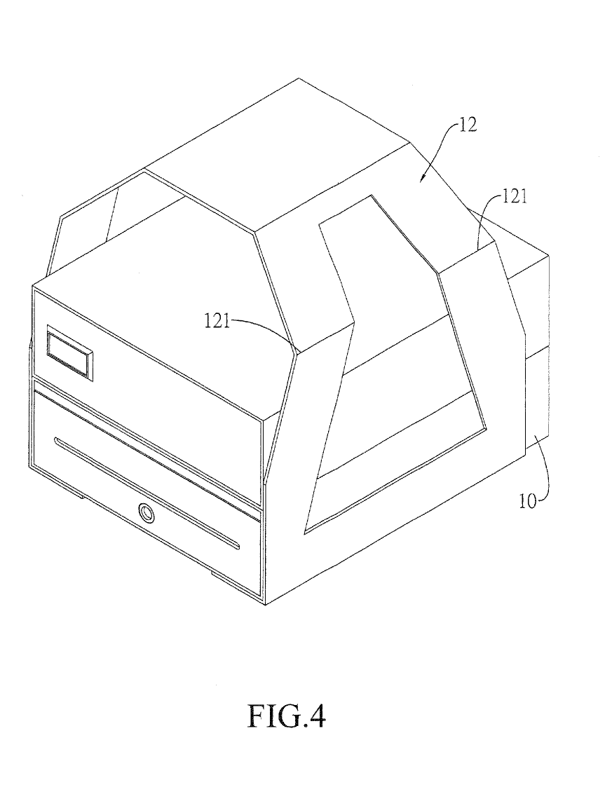

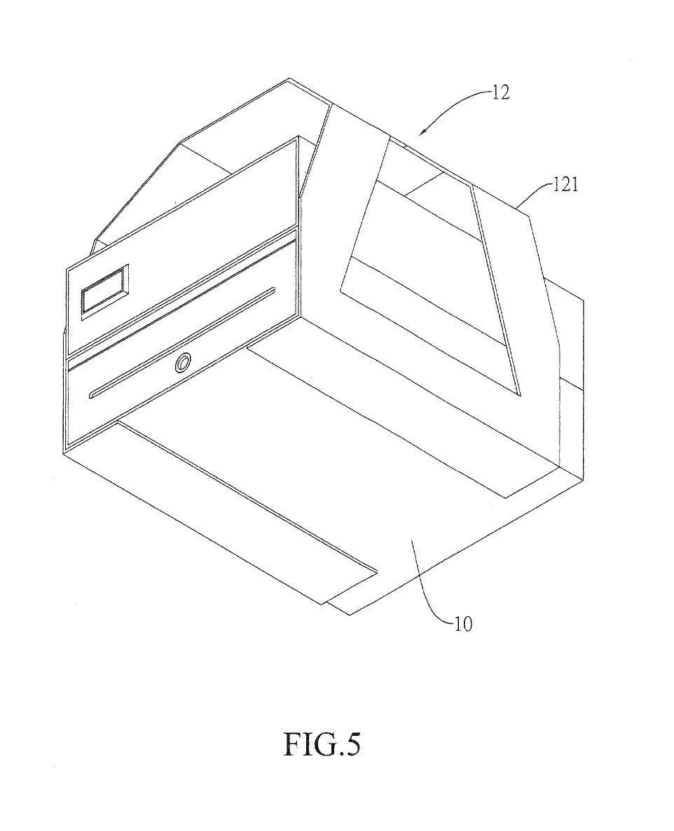

As shown in FIGS. 4 and 5, in an alternative embodiment, a metallic handle 12 is configured on the casing 10, which is extended from a first lateral portion of a bottom side, up along a first lateral side, across a top side, down along a second lateral side, and then back to a second lateral portion of the bottom side of the casing 10. As such, heat could be further dissipated through the handle 12 for faster dissipation. In addition, the handle 12 is bended above the top side of the casing 10 to form corners 121 to facilitate hand grasping and therefore the transportation of the casing 10.

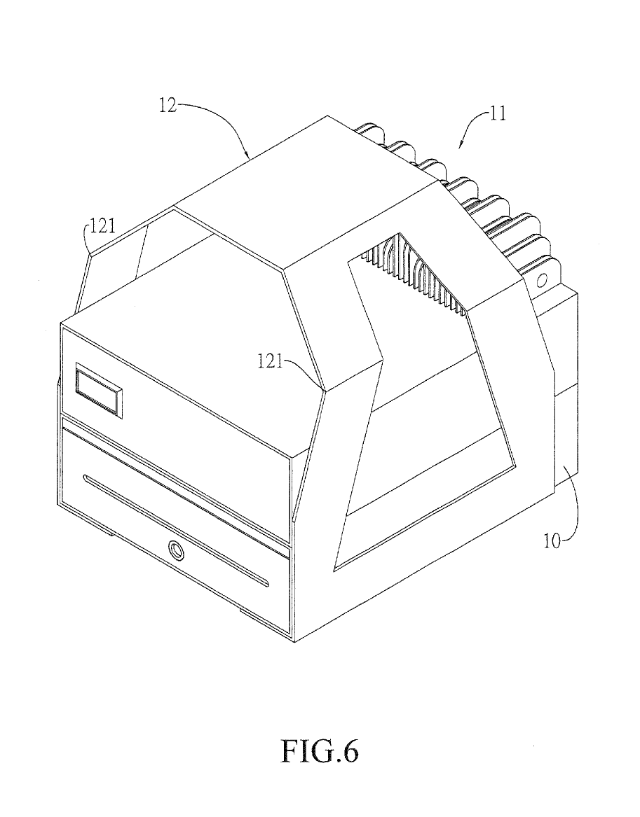

As shown in FIG. 6, both the handle 12 and the fins 11 could be jointly implemented for significantly enhancing the heat dissipating efficiency.

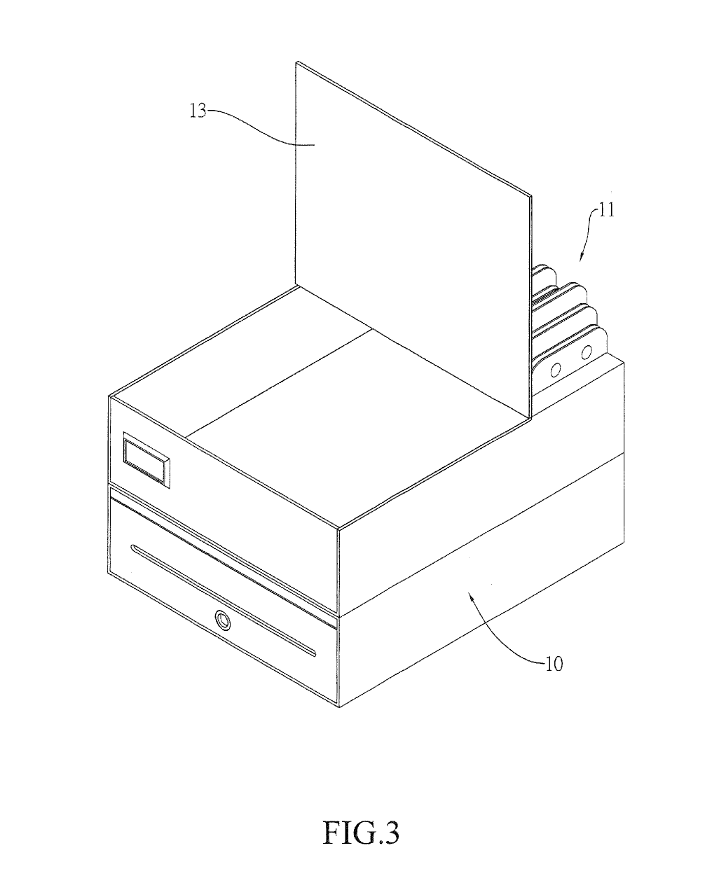

As shown in FIGS. 2 and 3, the top side of the casing 10 is configured with a door 13 that could be opened and closed for easy access the components installed inside the casing 10.

The heat conducting paste 30 could be a heat conducting silicone and the heat conducting block 20 could be made of aluminum alloy or copper.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A heat dissipating casing structure for a main board, comprising:
a metallic casing;
a metallic heat conducting positioned inside and attached to said casing; and
a heat conducting paste disposed on said heat conducting block;
wherein, when said main board is positioned inside said casing, said heat conducting paste is behind a heat source of said main board and is attached to said main board.

2. The heat dissipating casing structure according to claim 1, wherein said casing is configured with a plurality of heat dissipating fins.

3. The heat dissipating casing structure according to claim 2, wherein said heat conducting fins are threaded by a heat conducting pipe.

4. The heat dissipating casing structure according to claim 3, wherein a metallic handle is configured on said casing 10, which is extended from a first lateral portion of a bottom side, up along a first lateral side, across a top side, down along a second lateral side, and then back to a second lateral portion of said bottom side of said casing.

5. The heat dissipating casing structure according to claim 4, wherein said handle is bended above said top side of said casing 10 to form at least a corner.

6. The heat dissipating casing structure according to claim 5, wherein said heat conducting paste is a heat conducting silicone.

7. The heat dissipating casing structure according to claim 6, wherein said heat conducting block is made of one of aluminum alloy and copper.

8. The heat dissipating casing structure according to claim 7, wherein said top side of said casing is configured with a door.

9. The heat dissipating casing structure according to claim 8, wherein said heat source is one of a central processing unit and a Northbridge/Southbridge chip.
